(19) United States
(12) Patent Application Publication
(10) Pub. No.: US 2012/0142159 A1
(43) Pub. Date: Jun. 7, 2012

(54) METHOD FOR FABRICATING SEMICONDUCTOR DEVICE

(75) Inventors: Tae-Gon Kim, Seoul (KR); Sang-Bom Kang, Seoul (KR); Jae-Young Park, Yongin-si (KR); Kang-Hun Moon, Osan-si (KR); Hyun-Jun Sim, Hwaseong-si (KR); Seung-Hun Lee, Seoul (KR); Han-Ki Lee, Hwaseong-si (KR); Hyun-Seung Kim, Bucheon-si (KR)

(73) Assignee: SAMSUNG ELECTRONICS CO., LTD., Suwon-si (KR)

(21) Appl. No.: 13/242,302

(22) Filed: Sep. 23, 2011

(30) Foreign Application Priority Data
Dec. 6, 2010 (KR) 10-2010-0123595

(51) Int. Cl. H01L 21/336; H01L 21/20

(52) U.S. Cl. 438/300; 438/478; 257/E21.409; 257/E21.09

(57) ABSTRACT

Methods for fabricating a semiconductor device are provided wherein, in an embodiment, the method includes the steps of forming a gate electrode on a semiconductor substrate, forming a trench by recessing the semiconductor substrate in the vicinity of the gate electrode, doping an anti-diffusion ion into a portion of the semiconductor substrate in the trench, and growing an impurity-doped epitaxial layer on the semiconductor substrate doped with the anti-diffusion ion.

### CROSS-REFERENCE TO RELATED APPLICATION

This application claims priority from Korean Patent Application No. 10-2010-0123595 filed on Dec. 6, 2010 in the Korean Intellectual Property Office, and all the benefits accruing therefrom under 35 U.S.C. 119, the contents of which in its entirety are herein incorporated by reference.

### FIELD

The present invention relates to methods for fabricating semiconductor devices, particularly transistors.

### BACKGROUND

A transistor is a type of semiconductor device having various applications in electronic devices. Smaller transistor size is desirable because the smaller size makes it possible to construct smaller electronic devices incorporating such transistors.

Efforts to scale down the size of a transistor, however, encounter various types of performance limitations. One of those performance limitations is known as the “short channel effect” that lowers the performance of the transistor, and various attempts are being made to overcome the short channel effect.

### SUMMARY

Embodiments of the present inventive concept provide methods for fabricating a semiconductor device having an improved short channel effect.

The above and other objects of the present inventive concept will be described in or be apparent from the following description of embodiments.

According to an aspect of the present inventive concept, there is provided a method for forming a semiconductor device. The method comprises the sequential steps of: (a) forming a gate electrode on a semiconductor substrate; (b) forming a trench by recessing the semiconductor substrate in the vicinity of the gate electrode; (c) doping an anti-diffusion ion into at least a portion of the semiconductor substrate in the trench; and, (d) growing an impurity-doped epitaxial layer on the portion of the semiconductor substrate doped with the anti-diffusion ion.

In some embodiments, the anti-diffusion ion is an arsenic (As) ion.

In some embodiments, the step of doping of the arsenic ion into the semiconductor substrate comprises a step of ion implanting the arsenic ion into the semiconductor substrate.

In some embodiments, the ion implanting step comprises an angled ion implanting procedure.

In some embodiments, the steps of doping the arsenic ion into the semiconductor substrate comprises the sub-steps of: forming an arsenic ion layer on the semiconductor substrate in the trench; and diffusing arsenic ion from the arsenic ion layer into the semiconductor substrate in the trench.

In some embodiments, an impurity in the impurity-doped epitaxial layer is phosphorus (P).

In some embodiments, the semiconductor device comprises an nMOS transistor.

In some embodiments, the impurity-doped epitaxial layer becomes a source/drain of the nMOS transistor.

In some embodiments, the source/drain is an elevated source/drain.

In some embodiments, the method further comprises a step of annealing the semiconductor substrate doped with the anti-diffusion ion after step (c) and prior to step (d).

In some embodiments, the annealing step comprises annealing the semiconductor substrate doped with the anti-diffusion ion at a temperature of about 900° C. to about 1300° C. for about 1 to 2 seconds.

In another aspect, a method for forming a semiconductor device comprises the sequential steps of: (a) forming a gate electrode on a semiconductor substrate; (b) forming a trench by recessing the semiconductor substrate in the vicinity of the gate electrode; (c) growing a first epitaxial layer doped with an anti-diffusion ion on the semiconductor substrate in the trench; and (d) growing a second epitaxial layer doped with an impurity on the first epitaxial layer.

In some embodiments, the anti-diffusion ion is arsenic (As) ion.

In some embodiments, an impurity in the second epitaxial layer is phosphorus (P).

In some embodiments, the method further comprises a step of annealing the semiconductor substrate having the first epitaxial layer thereon after step (c) and prior to step (d).

In another aspect, in a method of fabricating a semiconductor device that includes the steps of forming a gate electrode on a semiconductor substrate, forming a trench in the semiconductor substrate in the vicinity of the gate electrode, and thereafter growing an epitaxial layer that is doped with an impurity in at least a portion of the trench, the improvement comprises the step of forming an anti-diffusion ion layer in or on the portions of the semiconductor substrate that are adjacent to the trench prior to the step of growing the epitaxial layer that is doped with an impurity, wherein the anti-diffusion ion layer includes an anti-diffusion ion that substantially prevents diffusion of the impurity from the doped epitaxial layer through the anti-diffusion ion layer.

In some embodiments, the step of forming the anti-diffusion ion layer comprises a step of introducing anti-diffusion ions into the portions of the semiconductor substrate that are adjacent to the trench.

In some embodiments, the step of introducing anti-diffusion ions comprises ion implantation procedures.

In some embodiments, the step of introducing anti-diffusion ions comprises the sub-steps of forming an ion-source layer containing the anti-diffusion ions on the portions of the semiconductor substrate that are adjacent to the trench and performing an annealing procedure that causes at least some of the anti-diffusion ions to diffuse from the ion-source layer into the adjacent portions of the semiconductor substrate.

In some embodiments, the step of forming the anti-diffusion ion layer comprises a step of forming an epitaxial layer doped with the anti-diffusion ions on the portions of the semiconductor substrate that are adjacent to the trench.

### BRIEF DESCRIPTION OF THE DRAWINGS

The above and other features and advantages of the present inventive concept will become more apparent by describing in detail preferred embodiments thereof with reference to the attached drawings in which:

FIG. 1 is a flowchart of a method for fabricating a semiconductor device according to an embodiment and a modified embodiment of the present inventive concept;

FIGS. 2 to 6 are schematic cross-sectional views illustrating intermediate process steps of a method for fabricating a semiconductor device according to an embodiment and a modified embodiment of the present inventive concept;

FIG. 7 is a flowchart of a method for fabricating a semiconductor device according to another embodiment and a modified embodiment of the present inventive concept;

FIGS. 8 and 9 are schematic cross-sectional views illustrating intermediate process steps of a method for fabricating a semiconductor device according to another embodiment and a modified embodiment of the present inventive concept; and

FIG. 10 is a graph illustrating a distribution of impurity, for example, phosphorus (P), concentrations depending on the depth of a semiconductor device according to embodiments of the present inventive concept.

### DETAILED DESCRIPTION OF EMBODIMENTS

Advantages and features of the present inventive concept and methods of accomplishing the same may be understood more readily by reference to the following detailed description of preferred embodiments and the accompanying drawings. The present inventive concept may, however, be embodied in many different fauns and should not be construed as being limited to the embodiments set forth herein. Rather, these embodiments are provided so that this disclosure will be thorough and complete and will fully convey the concept of the invention to those skilled in the art, and the present inventive concept will only be defined by the appended claims. In the drawings, the thickness of layers and regions are exaggerated for clarity. Like numbers refer to like elements throughout. As used herein, the term “and/or” includes any and all combinations of one or more of the associated listed items.

Unless otherwise defined, all terms (including technical and scientific terms) used herein have the same meaning as commonly understood by one of ordinary skill in the art to which this invention pertains. It will be further understood that terms, such as those defined in commonly used dictionaries, should be interpreted as having a meaning that is consistent with their meaning in the context of the relevant art and the present disclosure, and should not be interpreted in an idealized or overly formal sense unless expressly so defined herein.

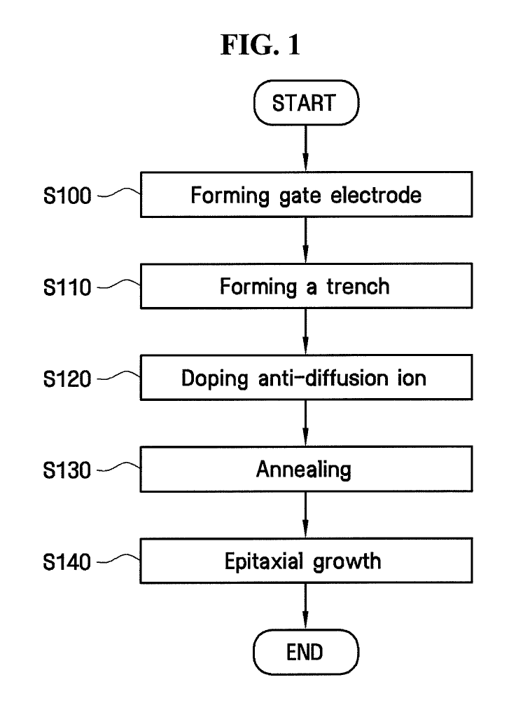

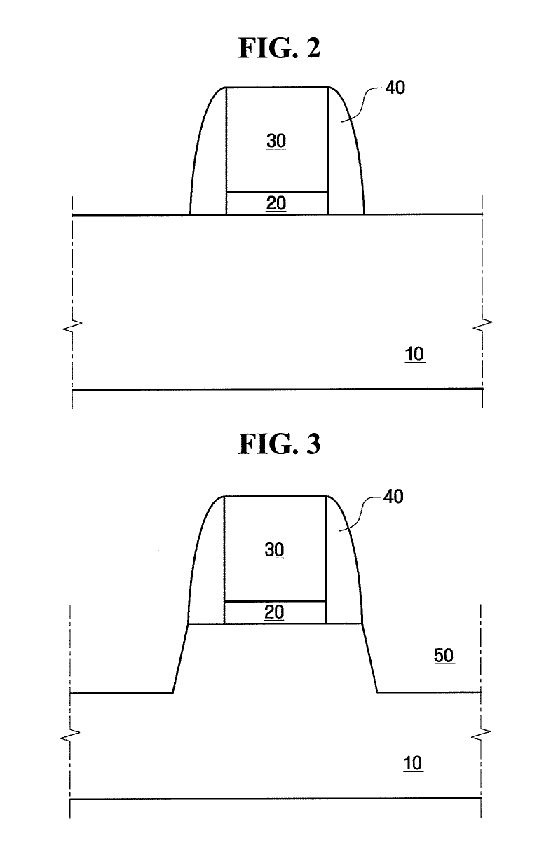

Hereinafter, a method for fabricating a semiconductor device according to an embodiment and a modified embodiment of the present inventive concept will be described with reference to FIGS. 1 to 6. FIG. 1 is a flowchart of a method for fabricating a semiconductor device according to an embodiment and a modified embodiment of the present inventive concept, and FIGS. 2 to 6 are schematic cross-sectional views illustrating intermediate process steps of a method for fabricating a semiconductor device according to an embodiment and a modified embodiment of the present inventive concept.

Referring first to FIGS. 1 and 2, a gate insulating layer 20, a gate electrode 30 and a gate spacer 40 are formed on a semiconductor substrate 10 (step S100 in FIG. 1). Step S100 may comprise a sequence of sub-steps. Specifically, an insulating layer (not shown) and a conductive layer (not shown) are first formed on the semiconductor substrate 10. Then, the conductive layer and the insulating layer are sequentially etched to form the gate electrode 30 and the gate insulating layer 20. Although not shown in FIG. 2, before forming the gate insulating layer 20, an isolation region (not shown) may first be formed on a predetermined portion of the semiconductor substrate 10 by a trench process or a LOCOS process to define an active region on which the semiconductor device is subsequently to be formed.

The semiconductor substrate 10 may be, for example, single crystal silicon (Si) substrate, and the gate insulating layer 20 may be made of various insulating materials, including silicon oxide, silicon oxynitride, metal oxide, metal oxynitride, and so on. In addition, the gate electrode 30 may be formed of a doped polysilicon layer, a metal such as tungsten, copper or aluminum, or a conductive metal layer such as a metal nitride layer.

Next, referring to FIGS. 1 and 3, the semiconductor substrate 10 in the vicinity of the gate insulating layer 20, the gate electrode 30 and the gate spacer 40 is recessed to form a trench 50 (step S110 in FIG. 1).

Next, referring to FIGS. 1, 4 and 5, an anti-diffusion ion is doped into a top portion of the semiconductor substrate 10 exposed by the trench 50 (step S120 in FIG. 1).

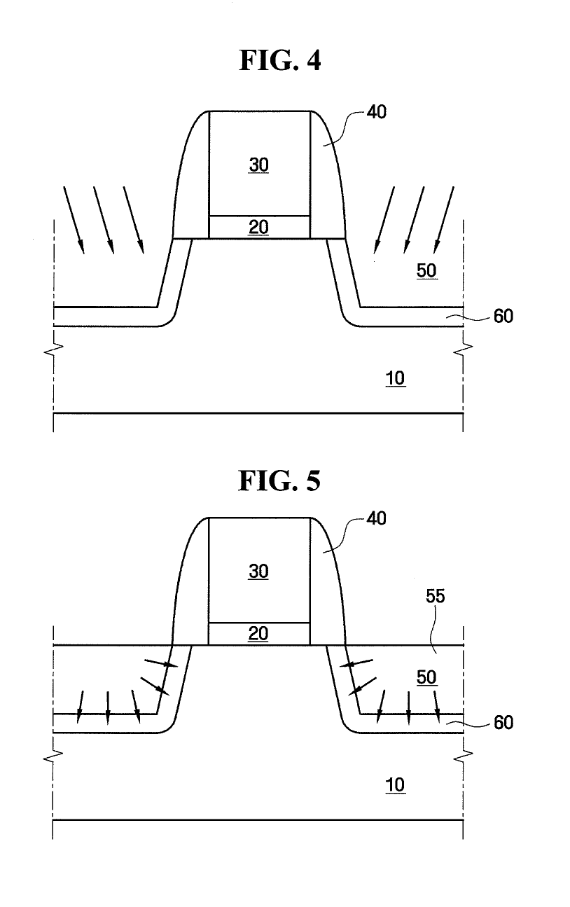

Step S120 may comprise sub-steps performed sequentially or simultaneously. Specifically, referring first to FIG. 4, in the method for fabricating a semiconductor device according to this embodiment of the present inventive concept, an anti-diffusion layer 60 is formed on the top portion of the semiconductor substrate 10 that is exposed by the trench 50 by ion implanting an anti-diffusion ion on that top portion. The anti-diffusion layer 60 prevents impurities in a source/drain subsequently to be formed in the trench 50 from diffusing into the semiconductor substrate 10. Arsenic (As), for example, may be used as the anti-diffusion ion.

However, it is preferable to substantially evenly implant the anti-diffusion ion on portions, including sidewall portions, of the substrate that are adjacent to the trench 50. To this end, a combination of a flat ion implantation and an angled ion implantation method may be used. In order to evenly implant anti-diffusion ion on the bottom surfaces and the sidewalls of the trench 50, flat ion implantation and angled ion implantation methods may be sequentially or simultaneously performed.

If the anti-diffusion ion is doped into the top portion of the semiconductor substrate 10 in the trench 50 using a controlled ion implantation process, the anti-diffusion layer 60 can be formed to a desired thickness with a desired concentration of the anti-diffusion ion, and thereby the characteristics of a semiconductor device can be accurately adjusted according to the needs of the device.

Referring to FIG. 5, in an alternative method for fabricating a semiconductor device according to a modified embodiment of the present inventive concept, an anti-diffusion ion-source layer 55 is first formed on the semiconductor substrate 10 in the trench 50. Therefore, an anti-diffusion layer 60 is formed by causing diffusion of an anti-diffusion ion from anti-diffusion ion-source layer 55 into a top portion of the semiconductor substrate 10 in the trench 50 by, for example, an annealing process.

As previously described in connection with the embodiment of the present inventive concept illustrated in FIG. 4, the anti-diffusion layer 60 as shown in FIG. 5 prevents impurities in a source/drain subsequently to be formed in the trench 50 from diffusing into a channel of the semiconductor substrate 10. Arsenic (As), for example, may be used as the anti-diffusion ion.

While the doping of an anti-diffusion ion into the top portion of the semiconductor substrate 10 in the trench 50 has been described with reference to the methods shown in FIGS. 4 and 5, the present invention is not limited thereto. Any other method may be used as long as the anti-diffusion ion (e.g., As) can be doped into the top portion of the semiconductor substrate 10 in the trench 50.

Next, referring again to FIG. 1, the semiconductor substrate 10 having the anti-diffusion layer 60 doped with the anti-diffusion ion is annealed (step S130 in FIG. 1).

The semiconductor substrate 10 is annealed at this stage of the fabrication process for the following reasons.

First, the annealing may activate the anti-diffusion ion (e.g., As) that was doped into the substrate in the previous step (S120). The thus-activated anti-diffusion ion can effectively prevent the impurities of the source/drain subsequently to be formed in the trench 50 from diffusing into the channel of the semiconductor substrate 10.

In addition, the annealing step allows an epitaxial layer to be more effectively grown in the trench 50 in a subsequent step (as described below). It has been found that single crystalline silicon particles, which can serve as seeds in an epitaxial growth process, are formed on the semiconductor substrate 10 in the trench 50 during the annealing step (S130). It has further been found that the epitaxial layer can be more effectively grown in the trench 50 using the single crystalline silicon particles formed during an annealing step as the seeds.

The annealing process (S130) performed for this purpose may include annealing the semiconductor substrate 10 having the anti-diffusion layer 60 at a temperature of about 900° C. to about 1300° C. for about 1 to 2 seconds, for example.

If the anti-diffusion ion-source layer 55 is formed on the semiconductor substrate 10 in the trench 50, the anti-diffusion ion-source layer 55 may be removed by selective etching process after annealing process.

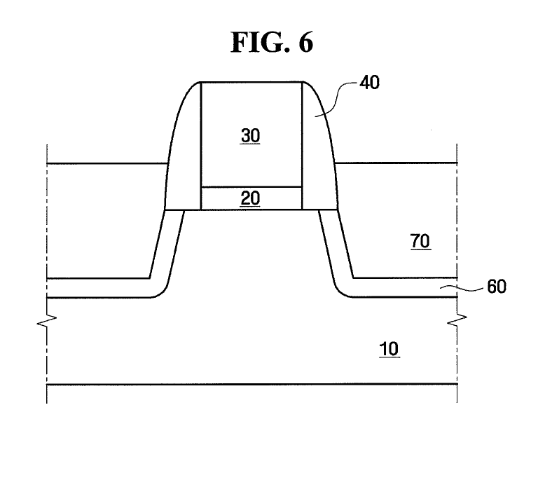

Next, referring to FIGS. 1 and 6, an epitaxial layer 70 doped with an impurity is grown (step S140 in FIG. 1) on the semiconductor substrate 10 having the anti-diffusion layer 60 doped with an anti-diffusion ion.

The thus formed semiconductor device shown in FIG. 6 may be, for example, an nMOS transistor. For this example, the impurity may be an n-type impurity, for example, phosphorus (P). The epitaxial layer 70 doped with an impurity (e.g., phosphorus (P)) grown on the semiconductor substrate 10 having the anti-diffusion layer 60 may function as an elevated source/drain of the nMOS transistor, as shown in FIG. 6. The elevated source/drain serves to increase a channel length of the nMOS transistor (as compared to a non-elevated source/drain), thereby advantageously reducing the short channel effect of the nMOS transistor.

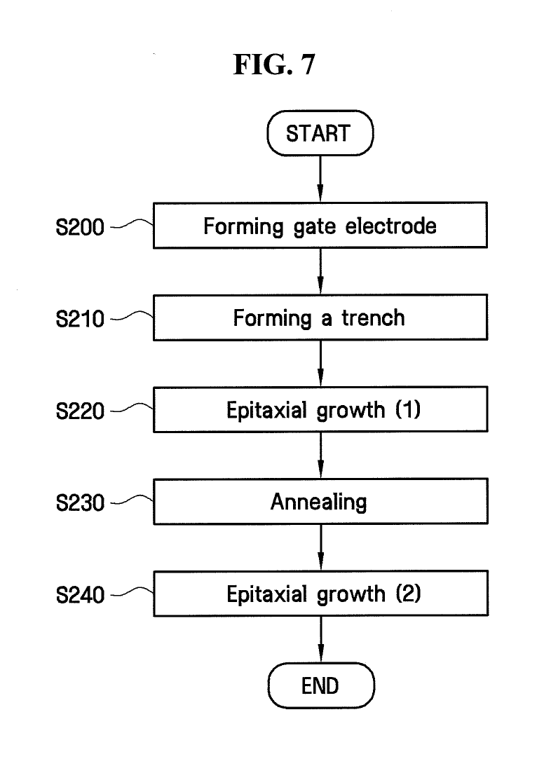

Next, a method for fabricating a semiconductor device according to another embodiment of the present inventive concept will be described with reference to FIGS. 7 to 9.

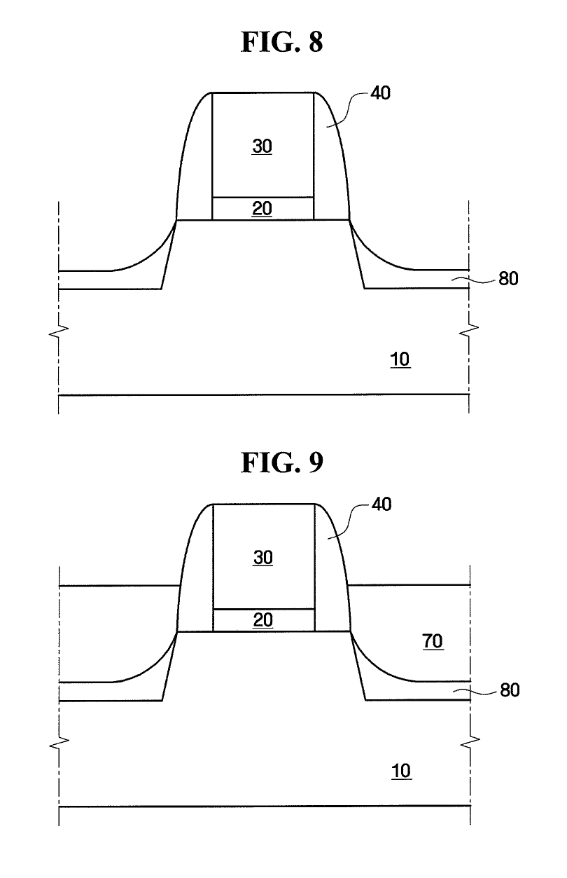

FIG. 7 is a flowchart of a method for fabricating a semiconductor device according to another embodiment and a modified embodiment of the present inventive concept, and FIGS. 8 and 9 are schematic cross-sectional views illustrating intermediate process steps of a method for fabricating a semiconductor device according to another embodiment and a modified embodiment of the present inventive concept.

Referring first to FIG. 7, taken together with FIGS. 2 and 3, a gate insulating layer 20, a gate electrode 30 and a gate spacer 40 are formed on the semiconductor substrate 10 (step S200 in FIG. 7). The semiconductor substrate 10 in the vicinity of the gate insulating layer 20, the gate electrode 30 and the gate spacer 40 is recessed to form a trench 50 (step S210 in FIG. 7). The steps S200 and S210 in FIG. 7 are substantially the same as steps S100 and S110, respectively, in FIG. 1, according to the previously-described embodiments of the present inventive concept, and therefore repeated descriptions thereof will be omitted.

Next, referring to FIGS. 7 and 8, a first epitaxial layer 80 doped with an anti-diffusion ion is grown on a top portion of the semiconductor substrate 10 in the trench 50 (step S220 in FIG. 7). In contrast to the FIG. 1 invention embodiments, in the method for fabricating the semiconductor device according to the FIG. 7 embodiments of the present inventive concept, ion implantation or diffusion is not used to form an anti-diffusion layer (e.g., the layer 60 of FIGS. 4 and 5) having an anti-diffusion ion. Instead, in the FIG. 7 invention embodiments, the first epitaxial layer 80 doped with an anti-diffusion ion is grown on the top portion of the semiconductor substrate 10 in the trench 50, as shown in FIGS. 8 and 9.

Because the first epitaxial layer 80 is doped with an anti-diffusion ion, layer 80 serves to prevent an impurity of a source/drain subsequently to be formed in the trench 50 from diffusing into a channel of the semiconductor substrate 10, thereby acting like the anti-diffusion layer 60 of FIGS. 4 and 5. Arsenic (As), for example, may be used as the anti-diffusion ion in layer 80.

Next, referring again to FIG. 7, the semiconductor substrate 10 having the first epitaxial layer 80 doped with the anti-diffusion ion is annealed (step S230 in FIG. 7). The step S230 is substantially the same as step S130 in FIG. 1, as described above, and a detailed description thereof will be omitted.

Next, referring to FIGS. 7 and 9, a second epitaxial layer 70 doped with an impurity is grown on the first epitaxial layer 80 (step S240 in FIG. 7).

The thus formed semiconductor device shown in FIG. 9 may, similar to the device of FIG. 6, be, for example, an nMOS transistor. For this example, the impurity may be an n-type impurity, for example, phosphorus (P). The second epitaxial layer 70 doped with an impurity (e.g., phosphorus (P)) grown on the semiconductor substrate 10 having the first epitaxial layer 80 may function as an elevated source/drain of the nMOS transistor, as shown in FIG. 9. The elevated source/drain serves to increase a channel length of the nMOS transistor (as compared to a non-elevated source/drain), thereby advantageously reducing the short channel effect of the nMOS transistor.

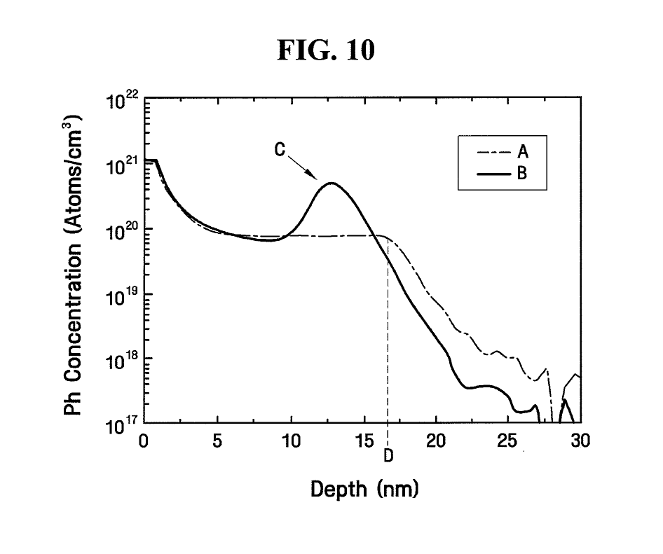

Next, the reduced short channel effect characteristics of a semiconductor device according to embodiments of the present inventive concept will be described with reference to FIG. 10.

FIG. 10 is a graph illustrating a distribution of concentrations of an impurity, specifically phosphorus (P), depending on the depth of a semiconductor device according to embodiments of the present inventive concept.

Referring to FIG. 10, a semiconductor device B having the anti-diffusion layer 60 (FIG. 6) that includes an anti-diffusion ion (e.g., arsenic (As)), or having the first epitaxial layer 80 (FIG. 9), has the following characteristics, as compared to a different semiconductor device A without the anti-diffusion layer 60 or the first epitaxial layer 80.

First, the concentration of impurity (e.g., phosphorus (P)) in source/drain of the semiconductor device B having the anti-diffusion layer 60 including an anti-diffusion ion (e.g., arsenic (As)) or the first epitaxial layer 80 is higher than that of the semiconductor device A without the anti-diffusion layer 60 or the first epitaxial layer 80.

Second, the heavily doped impurity (e.g., phosphorus (P)) layer C is not formed over the entire region of the source/drain but formed adjacent to an interface D between source/drain and semiconductor substrate 10.

This characteristic is demonstrated for the following reasons. First, as described above, the anti-diffusion layer 60 or the first epitaxial layer 80 prevents the impurity included in the source/drain, e.g., phosphorus (P), from being diffused into the channel region of the semiconductor substrate 10. In addition, the anti-diffusion layer 60 or the first epitaxial layer 80 forms a heavily doped impurity (e.g., phosphorus (P)) layer C adjacent to the interface D between the source/drain and the semiconductor substrate 10.

If the heavily doped impurity (e.g., phosphorus (P)) layer C is formed in the source/drain, a heavily doped source/drain can be implemented, thereby improving the short channel effect.

In addition, in a case where the source/drain is formed to include the heavily doped impurity (e.g., phosphorus (P)) over the entire region of the source/region in order to improve the short channel effect, roughness of a surface of the semiconductor substrate 10 may be increased. In the present invention, the heavily doped impurity (e.g., phosphorus (P)) layer C is formed only in the vicinity of the interface D between the source/drain and the semiconductor substrate 10 by is not formed entire region of the source/region but formed adjacent to the interface D by forming the anti-diffusion layer 60 or the first epitaxial layer 80, thereby preventing the roughness from increasing.

Therefore, according to the methods for fabricating semiconductor devices according to embodiments of the present inventive concept, a semiconductor device (e.g., an nMOS transistor) having a greatly improved short channel effect can be fabricated.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

What is claimed is:

1. A method for forming a semiconductor device, the method comprising the sequential steps of:
(a) forming a gate electrode on a semiconductor substrate;
(b) forming a trench by recessing the semiconductor substrate in the vicinity of the gate electrode;
(c) doping an anti-diffusion ion into at least a portion of the semiconductor substrate in the trench; and,
(d) growing an impurity-doped epitaxial layer on the portion of the semiconductor substrate doped with the anti-diffusion ion.

2. The method of claim 1, wherein the anti-diffusion ion is an arsenic (As) ion.

3. The method of claim 2, wherein the step of doping of the arsenic ion into the semiconductor substrate comprises a step of ion implanting the arsenic ion into the semiconductor substrate.

4. The method of claim 3, wherein the ion implanting step comprises an angled ion implanting procedure.

5. The method of claim 2, wherein the steps of doping the arsenic ion into the semiconductor substrate comprises the sub-steps of:
forming an arsenic ion layer on the semiconductor substrate in the trench; and,
diffusing arsenic ion from the arsenic ion layer into the semiconductor substrate in the trench.

6. The method of claim 1, wherein an impurity in the impurity-doped epitaxial layer is phosphorus (P).

7. The method of claim 1, wherein the semiconductor device comprises an nMOS transistor.

8. The method of claim 7, wherein the impurity-doped epitaxial layer becomes a source/drain of the nMOS transistor.

9. The method of claim 8, wherein the source/drain is an elevated source/drain.

10. The method of claim 1, further comprising a step of annealing the semiconductor substrate doped with the anti-diffusion ion.

11. The method of claim 10, wherein the annealing step comprises annealing the semiconductor substrate doped with the anti-diffusion ion at a temperature of about 900° C. to about 1300° C. for about 1 to 2 seconds.

12. A method for forming a semiconductor device comprising the sequential steps of:
(a) forming a gate electrode on a semiconductor substrate;
(b) forming a trench by recessing the semiconductor substrate in the vicinity of the gate electrode;
(c) growing a first epitaxial layer doped with an anti-diffusion ion on the semiconductor substrate in the trench; and,
(d) growing a second epitaxial layer doped with an impurity on the first epitaxial layer.

13. The method of claim 12, wherein the anti-diffusion ion is arsenic (As) ion.

14. The method of claim 12, wherein an impurity in the second epitaxial layer is phosphorus (P).

15. The method of claim 12, further comprising a step of annealing the semiconductor substrate having the first epitaxial layer thereon.

16. In a method of fabricating a semiconductor device that includes the steps of forming a gate electrode on a semiconductor substrate, forming a trench in the semiconductor substrate in the vicinity of the gate electrode, and thereafter growing an epitaxial layer that is doped with an impurity in at least a portion of the trench, the improvement comprising the step of forming an anti-diffusion ion layer in or on the portions of the semiconductor substrate that are adjacent to the trench prior to the step of growing the epitaxial layer that is doped with an impurity, wherein the anti-diffusion ion layer includes an anti-diffusion ion that substantially prevents diffusion of the impurity from the doped epitaxial layer through a channel region of the semiconductor substrate.

17. The method of claim 16 wherein the step of forming the anti-diffusion ion layer comprises a step of introducing anti-diffusion ions into the portions of the semiconductor substrate that are adjacent to the trench.

18. The method of claim 17 wherein the step of introducing anti-diffusion ions comprises ion implantation procedures.

19. The method of claim 17 wherein the step of introducing anti-diffusion ions comprises the sub-steps of forming an ion-source layer containing the anti-diffusion ions on the portions of the semiconductor substrate that are adjacent to the trench and performing an annealing procedure that causes at least some of the anti-diffusion ions to diffuse from the ion-source layer into the adjacent portions of the semiconductor substrate.

20. The method of claim 16 wherein the step of forming the anti-diffusion ion layer comprises a step of forming an epitaxial layer doped with the anti-diffusion ions on the portions of the semiconductor substrate that are adjacent to the trench.
